(19) United States
(12) Patent Application Publication
(10) Pub. No.: US 2026/0324496 A1
(43) Pub. Date: Oct. 15, 2026

(54) METAL-CERAMIC COMPOSITE COMPONENT, ELECTRICAL APPARATUS, AND METHOD OF MANUFACTURING METAL-CERAMIC COMPOSITE COMPONENT

(71) Applicant: NGK CORPORATION, Nagoya-shi (JP)

(72) Inventors: Naoya SHIRAI, Sanyo-Onoda-shi (JP); Akiyoshi OSAKADA, Mine-shi (JP)

(21) Appl. No.: 19/690,267

(22) Filed: May 28, 2026

Related U.S. Application Data
(63) Continuation of application No. PCT/JP2024/042280, filed on Nov. 29, 2024.

(30) Foreign Application Priority Data
Dec. 1, 2023 (WO) PCT/JP2023/043125

(51) Int. Cl. H10W 76/18; H10W 40/00; H10W 40/20; H10W 40/22; H10W 40/25; H10W 72/00; H10W 72/30; H10W 76/01; H10W 90/00

(52) U.S. Cl. CPC H10W 76/18; H10W 40/03; H10W 40/226; H10W 40/233; H10W 40/237; H10W 40/242; H10W 40/258; H10W 72/352; H10W 72/365; H10W 76/01; H10W 90/736; H10W 72/884; H10W 90/757

(57) ABSTRACT

A metal-ceramic composite component includes: a heat dissipating member including an upper surface and a lower surface opposite to the upper surface, and made of a metal sintered material; a ceramic body including a facing surface facing the upper surface of the heat dissipating member in a thickness direction and a front surface opposite to the facing surface; and an adhesive layer including a first interface having contact with the facing surface of the ceramic body and a second interface opposite to the first interface and having contact with the upper surface of the heat dissipating member. The adhesive layer is made of a composite material including both ceramic and metal, and the composite material is sintered with the ceramic material of the ceramic body at the first interface and sintered with the metal sintered material of the heat dissipating member at the second interface.

### CROSS-REFERENCE TO RELATED APPLICATION

This application is a continuation application of PCT/JP2024/042280, filed on Nov. 29, 2024, which claims the benefit of priority of International Patent Application No. PCT/JP2023/043125, filed on Dec. 1, 2023, the entire contents of which are incorporated herein by reference.

### BACKGROUND

### Technical Field

The present invention relates to a metal-ceramic composite component, an electrical apparatus, and a method of manufacturing a metal-ceramic composite component.

### Description of the Background Art

Japanese Patent Application Laid-Open No. 2015-204426 discloses a package. This package includes a heat sink plate and a ceramic frame. The heat sink plate is a rectangular metal plate for dissipating heat generated from an electronic component mounted to an upper surface thereof. The ceramic frame is joined to the heat sink plate to surround a site where the electronic component is mounted. They are joined by brazing. A brazing temperature is approximately 780 °C. The ceramic frame is formed of alumina or aluminum nitride, for example.

The above-mentioned ceramic frame has a frame-like shape, and is made up of a joint body of an upper layer sheet and a lower layer sheet. A metallization film and a plate covering film are provided to a lower surface of the lower layer sheet. The plate covering film on the lower surface of the lower layer sheet and the heat sink plate are joined via a brazing material. An inner periphery end of the lower layer sheet is located to be deviated closer to an outer periphery than an inner periphery end of the upper layer sheet. Accordingly, even when the electrical component gets close to an inner periphery of the upper layer sheet of the ceramic frame, the electrical component can be mounted away from a fillet of the brazing material.

The above-mentioned heat sink plate is a metal plate. As the metal plate, a metal plate having high thermal conductivity and capable of mitigating warpage of the package caused by a difference in coefficient of linear expansion from the ceramic frame during brazing is selected. For example, a composite metal plate or a clad metal plate is used. The composite metal plate is formed by impregnating method, for example. Specifically, it is formed by impregnating a porous refractory metal plate with Cu. Refractory metal, such as tungsten or molybdenum, has a close coefficient of linear expansion to ceramic; thus, the heat sink plate can have a close coefficient of linear expansion to the ceramic frame. Since Cu has excellent thermal conductivity, the heat sink plate can have high heat dissipating performance.

When the heat sink plate is required to have a close coefficient of linear expansion to the ceramic frame, the composite metal plate or the clad metal plate is widely used as described above. When a match between coefficients of linear expansion is not important, a simple metal material is also widely used, and thermal conductivity can significantly be increased by using pure copper, for example.

Considered in Japanese Patent Application Laid-Open No. 51-132461 is a manufacturing method in which brazing between a metal plate and a frame-like ceramic plate is not necessary. Specifically disclosed as a first manufacturing method is a manufacturing method in which a frame-like unfired ceramic plate (green sheet) is disposed on an Mo metal plate, directly bonded by hot press, and then fired. Since a surface of the metal plate is flat in the first manufacturing method, mutual penetration between materials of metal and ceramic is hardly performed in joining. Thus, joint strength between the metal plate and the ceramic plate is extremely small. Accordingly, the above-mentioned patent document discloses a manufacturing method, as a second manufacturing method, an unfired ceramic plate is disposed on one main surface of a metal plate made of refractory metal (for example, molybdenum or tungsten) via a metal powder layer made of refractory metal, and then fired. According to the argument of the above-mentioned patent document, the metal powder layer intervenes; thus, the above-mentioned mutual penetration is easily performed. Furthermore, the metal plate and the metal powder layer are easily joined by reason that they are made of homogeneous materials, thus have large joint strength. Accordingly, joint strength gets large.

### SUMMARY

Japanese Patent Application Laid-Open No. 51-132461 described above argues that large joint strength is obtained between the metal plate (a heat dissipating member made of metal) and the ceramic plate (a frame made of a ceramic material) without brazing. However, according to the inventor's study, it falls far short of practical joint strength. In fact, even decades after the disclosure of Japanese Patent Application Laid-Open No. 51-132461, a heat dissipating member made of metal and a frame made of a ceramic material are typically joined by brazing as disclosed in the above-mentioned Japanese Patent Application Laid-Open No. 2015-204426, for example.

The present disclosure has been conceived to solve a problem as described above, and it is an object of the present disclosure to provide a metal-ceramic composite component, an electrical apparatus, and a method of manufacturing a metal-ceramic composite component capable of ensuring practically sufficient joint strength between a ceramic body made of a ceramic material (for example, a frame made of a ceramic material) and a heat dissipating member made of metal without brazing between the ceramic body and the heat dissipating member.

A metal-ceramic composite component according to the present disclosure includes: a heat dissipating member including an upper surface and a lower surface opposite to the upper surface, and made of a metal sintered material; a ceramic body including a facing surface facing the upper surface of the heat dissipating member in a thickness direction and a front surface opposite to the facing surface, and made of a ceramic material; and an adhesive layer including a first interface having contact with the facing surface of the ceramic body and a second interface opposite to the first interface and having contact with the upper surface of the heat dissipating member. The adhesive layer is made of a composite material including both ceramic and metal, and the composite material is sintered with the ceramic material of the ceramic body at the first interface and sintered with the metal sintered material of the heat dissipating member at the second interface.

These and other objects, features, aspects and advantages of the present invention will become more apparent from the following detailed description when taken in conjunction with the accompanying diagrams.

### BRIEF DESCRIPTION OF THE DRAWINGS

FIG. 1 is a schematic cross-sectional view illustrating a configuration of an electrical apparatus according to an embodiment 1.

FIG. 2 is a schematic cross-sectional view illustrating a configuration of a package according to the embodiment 1.

FIG. 3 is a schematic cross-sectional view illustrating a first step of a method of manufacturing the package in FIG. 2.

FIG. 4 is a schematic cross-sectional view illustrating a second step of the method of manufacturing the package in FIG. 2.

FIG. 5 is a schematic cross-sectional view illustrating a third step of the method of manufacturing the package in FIG. 2.

FIG. 6 is a schematic cross-sectional view illustrating a fourth step of the method of manufacturing the package in FIG. 2.

FIG. 7 is a schematic partial cross-sectional view illustrating one example of a configuration near an outer end surface of an adhesive layer in the package according to the embodiment 1.

FIG. 8 is a schematic partial cross-sectional view illustrating another example of the configuration near the outer end surface of the adhesive layer in the package according to the embodiment 1.

FIG. 9 is a schematic partial cross-sectional view illustrating occurrence of migration of silver in the electrical apparatus in FIG. 1.

FIG. 10 is a schematic cross-sectional view illustrating a configuration of an electrical apparatus according to an embodiment 2.

FIG. 11 is a schematic cross-sectional view illustrating a configuration of an electrical apparatus according to an embodiment 3.

FIG. 12 is a schematic partial cross-sectional view illustrating stress on the adhesive layer in the electrical apparatus in FIG. 1.

FIG. 13 is a schematic patrial cross-sectional view illustrating a configuration of an electrical apparatus according to an embodiment 4.

FIG. 14 is a schematic cross-sectional view illustrating a configuration of an electrical apparatus according to an embodiment 5.

FIG. 15 is a schematic cross-sectional view illustrating a configuration of an electrical apparatus according to an embodiment 6.

FIG. 16 is a schematic partial cross-sectional view illustrating an example of a configuration near a corner portion made by a front surface and an outer surface of a frame in the package in FIG. 2.

FIG. 17 is a schematic partial cross-sectional view illustrating an example of a configuration near a corner portion made by a front surface and an outer surface of a frame in a package according to an embodiment 7.

FIG. 18 is a schematic cross-sectional view illustrating a configuration of a package according to an embodiment 8.

FIG. 19 is a schematic cross-sectional view illustrating a configuration of a package according to a modification example 1 of the embodiment 8.

FIG. 20 is a schematic cross-sectional view illustrating a configuration of a package according to a modification example 2 of the embodiment 8.

FIG. 21 is a schematic cross-sectional view illustrating a configuration of a package according to a modification example 3 of the embodiment 8.

FIG. 22 is a schematic cross-sectional view illustrating a configuration of a package according to a modification example 4 of the embodiment 8.

FIG. 23 is a schematic cross-sectional view illustrating a configuration of an electrical apparatus according to an embodiment 9.

FIG. 24 is a schematic perspective view illustrating a configuration of a package according to an embodiment 10.

### DESCRIPTION OF THE PREFERRED EMBODIMENTS

Embodiments of the present invention will be described below with reference to the diagrams. In the present specification, metal may indicate any of pure metal and metal alloy unless otherwise specified. Metal alloy may indicate any of a solid solution made of a plurality of metallic components, a mixture of plural types of metal which have not become a solid solution, or an intermetallic compound. The term of “green” indicates an unfired state. Thus, a member to which the term of “green” is assigned is to be sintered, but has not been fired yet. The terms of “upper” and “lower” are used to distinguish a relative direction, and does not indicate a limitation relating to a gravity direction unless otherwise specified.

### Embodiment 1

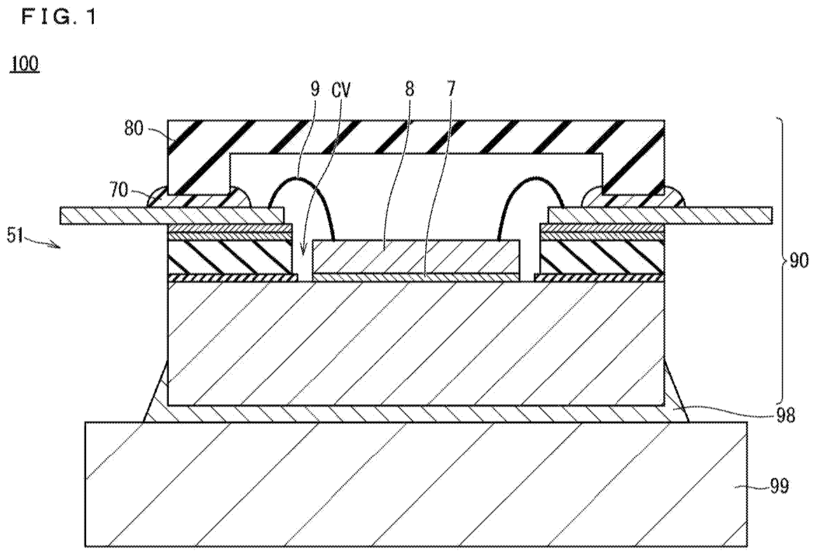

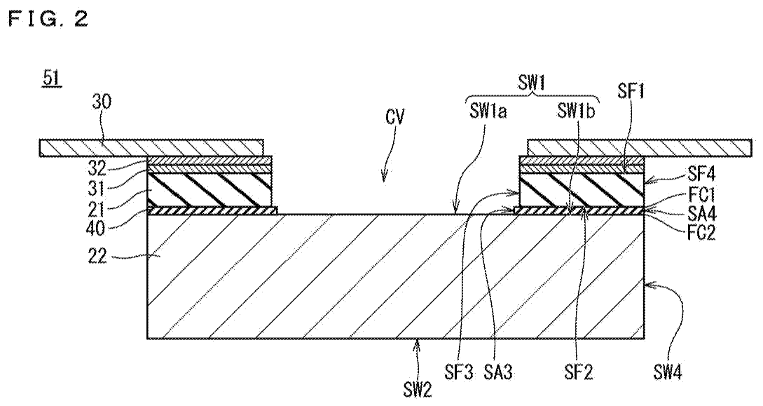

FIG. 1 is a schematic cross-sectional view illustrating a configuration of an electrical apparatus 100 according to an embodiment 1. FIG. 2 is a schematic cross-sectional view illustrating a configuration of a package 51 included in the electrical apparatus 100. The electrical apparatus 100 (FIG. 1) includes a semiconductor module 90 (an electrical apparatus), a heat sink 99, and a solder layer 98 (a joint layer). The solder layer 98 joins the semiconductor module 90 to the heat sink 99.

The semiconductor module 90 includes the package 51 with a cavity CV, a semiconductor element 8 (an electrical component) housed in the cavity CV, and a mounting material 7 for mounting the semiconductor element 8 on the package 51. The semiconductor module 90 may include wires 9 as wiring members for the semiconductor element 8. The wires 9 may be formed by wire bonding. In the example illustrated in FIG. 1, the wires 9 electrically connect the semiconductor element 8 and a lead frame 30. The semiconductor module 90 may include a lid 80 (FIG. 1) for sealing the cavity CV. The lid 80 may be attached to the package 51 by an adhesive portion 70.

Plating may be performed on the package 51 at an appropriate timing after a firing step described hereinafter. Plating is performed for typically forming a nickel plating film (not shown) as a ground and a gold plating film (not shown).

The semiconductor element 8 is mounted on a cavity surface SW1a included in an upper surface SW1 of a heat dissipating member 22 of the package 51 via the mounting material 7. The mounting material 7 has conductivity. The mounting material 7 may contain silver (Ag). The mounting material 7 may be formed by sintering an Ag paste, and the Ag paste may include a solvent and Ag powder with a nanosized diameter dispersed therein. Alternatively, the mounting material 7 may be formed by curing epoxy resin in which the Ag powder is dispersed. Alternatively, the mounting material 7 may be formed by soldering. This mounting step is typically performed using a mounting temperature of approximately 300 °C.

A distance from the semiconductor element 8 mounted to the package 51 and an inner surface SF3 of a frame 21 (a distance in a lateral direction in FIG. 1) may be equal to or smaller than 25 μm. This distance may also be zero. In other words, the semiconductor element 8 and the inner surface SF3 of the frame 21 may be in contact with each other. The reason the semiconductor element 8 can get close to the inner surface SF3 of the frame 21 is that brazing is not used to connect the frame 21 and the heat dissipating member 22 in the package 51. If brazing is used, a fillet of a brazing material is formed near the inner surface SF2 in the cavity CV, and tends to prevent the semiconductor element 8 from being disposed near the inner surface SF3. In the meanwhile, in the present embodiment, the semiconductor element 8 can be mounted close to the frame 21. Thus, a larger amount of a mounting area in the cavity CV can be ensured. When the semiconductor element 8 is mounted close to the frame 21, lengths of the wires 9 are reduced, and this normally leads to improvement of electrical characteristics.

The adhesive portion 70 may be thermosetting resin, for example. The adhesive portion 70 is disposed on the frame 21 to surround the cavity CV. The adhesive portion 70 may include a portion provided on the frame 21 via the lead frame 30 (a metal terminal). The adhesive portion 70 has a thickness between the lid 80 and the package 51 (a dimension in a vertical direction in FIG. 1) of 100 μm or more and 360 μm or less, for example.

With reference to FIG. 2, the package 51 has the cavity CV in which the semiconductor element 8 (FIG. 1) is to be housed. The package (a type of metal-ceramic composite component) 51 includes the heat dissipating member 22, the frame 21, and an adhesive layer 40. The package 51 may further include a metallization layer 31, a brazing material layer 32, and the lead frame 30.

The heat dissipating member 22 includes the upper surface SW1, a lower surface SW2 opposite to the upper surface SW1, and an outer wall surface SW4 mutually connecting the upper surface SW1 and the lower surface SW2. The upper surface SW1 faces the cavity CV. Specifically, the upper surface SW1 includes the cavity surface SW1a facing the cavity CV. The upper surface SW1 includes a surrounding edge surface SW1b located outside the cavity surface SW1a. The surrounding edge surface SW1b may surround the cavity surface SW1a. The cavity surface SW1a may be substantially a flat surface. The surrounding edge surface SW1b may be substantially a flat surface. In the example illustrated in FIG. 2, the upper surface SW1 is substantially a flat surface.

The heat dissipating member 22 is made of a metal sintered material. In the present specification, the metal sintered material indicates a sintered material substantially made of metal. The metal sintered material is substantially a metal material as described above, but may contain ceramic as an additive. A volume ratio of metal in the metal sintered material is preferably equal to or larger than 95 volume percent. The volume ratio may be 100 %, and in such a case, the metal sintered material contain only metal.

The metal sintered material may contain copper (Cu) and at least one refractory metal selected from the group consisting of tungsten (W) and molybdenum (Mo). When Cu is contained at a sufficient ratio, high thermal conductivity can be ensured. In the meanwhile, when refractory metal is contained at a sufficient ratio, the heat dissipating member can have a close coefficient of linear expansion to ceramic such as alumina. This approximateness of the coefficient of linear expansion is helpful for suppressing thermal stress between the heat dissipating member 22 and the frame 21. A ratio of Cu is equal to or larger than 10 volume percent and equal to or smaller than 60 volume percent, for example. The volume ratio can be calculated by a measured value of weight percent obtained by element analysis and a value (Cu: 8.96, W: 19.3, Mo: 10.28 (unit: g/cm³)) of density of each element. The metal sintered material may contain only one of W and Mo for simplifying a composition. In other words, the metal sintered material may be copper-tungsten alloy or copper-molybdenum alloy. The metal sintered material of copper-tungsten alloy or copper molybdenum alloy is a material different from clad material of copper/tungsten by necessity.

The frame 21 includes a facing surface SF2 facing the surrounding edge surface SW1b of the upper surface SW1 of the heat dissipating member 22, a front surface SF1 opposite to the facing surface SF2, an inner surface SF3 surrounding the cavity CV, and an outer surface SF4 opposite to the inner surface SF3. An outer edge of the frame 21 may have a rectangular shape in an in-plane direction perpendicular to a thickness direction. Each side of the rectangular shape has a length of 4 mm or more and 40 mm or less, for example. The frame 21 has a thickness of 0.1 mm or more and 1 mm or less, for example. The frame 21 is made of a ceramic material (i.e., the frame is a type of ceramic body). Accordingly, thermal resistance of the package 51 can be increased compared with a case where the frame 21 is made of a resin material. Since the ceramic material is an insulating body, the front surface SF1 of the frame 21 can be a surface electrically insulated from the heat dissipating member 22. The ceramic material contains alumina as a main component, for example. In such a case, the ceramic material may also contain an additive, and contains silicon oxide, manganic oxide, or both of them, for example.

The adhesive layer 40 includes an interface FC1 (a first interface) having contact with the facing surface SF2 of the frame 21 and an interface FC2 (a second interface) having contact with the upper surface SW1 of the heat dissipating member 22 opposite to the interface FC1. The adhesive layer 40 includes an outer end surface SA4 facing outward from the package 51. At least a part of the adhesive layer 40 has contact with the surrounding edge surface SW1b of the upper surface SW1 of the heat dissipating member 22. In the example illustrated in FIG. 2, the adhesive layer 40 has also further contact with a part of the cavity surface SW1a of the upper surface SW1 of the heat dissipating member 22. As illustrated in FIG. 2, the adhesive layer 40 can be disposed to have contact with only a part (not all) of the cavity surface SW1a, and in this case, the adhesive layer 40 includes an inner end surface SA3 facing the cavity CV.

The frame 40 is made of a composite material including both metal and ceramic. The composite material is sintered with the ceramic material of the frame 21 at the interface FC1 and is sintered with the metal sintered material of the heat dissipating member 22 at the interface FC2. Since Cu has a low melting point, Cu of the adhesive layer 40 and Cu of the heat dissipating member 22 may be melted and joined to each other. The frame 21 and the heat dissipating member 22 are fixed to each other using sintering at the interface FC1 and the interface FC2. Accordingly, the brazing material needs not be used for joining the frame 21 and the heat dissipating member 22 to each other. The brazing material normally contains Ag. When use of the brazing material is avoided, avoided is an Ag element as an element in which migration tends to occur located between the frame 21 and the heat dissipating member 22. A volume ratio of metal contained in the composite material of the adhesive layer 40 is smaller than that of the metal contained in the heat dissipating member 22.

The metal of the composite material may contain Cu and at least one refractory metal selected from the group consisting of W and Mo. A main component of ceramic of the composite material is alumina, for example. Ceramic may contain an additive in addition to alumina as a main component, and the additive is silicon oxide and manganic oxide, for example.

The composite material may include a material in common to the ceramic material of the frame 21. Accordingly, a difference of a sintering temperature of the adhesive layer 40 and the frame 21 in co-firing them time can be reduced. The composite material of the adhesive layer 40 may include a material in common to the metal sintered material of the heat dissipating member 22. Accordingly, joint strength between the adhesive layer 40 and the heat dissipating member 22 can be ensured more reliably in co-firing them.

The coefficient of linear expansion of the composite material of the adhesive layer 40 may be larger than that of the ceramic material of the frame 21 and smaller than that of the heat dissipating member 22. Such a relationship between the coefficients of linear expansion is easily obtained by making ceramic of the composite material of the adhesive layer 40 be similar to the ceramic material of the frame 21 and making the metal of the composite material of the adhesive layer 40 be similar to the metal sintered material of the heat dissipating member, for example.

The composite material preferably contains ceramic at a ratio of 20 volume percent or more and 80 volume percent or less. When the composite material contains ceramic at the ratio of 20 volume percent or more, joint strength of the frame 21 with respect to the ceramic material is increased. The composite material of the adhesive layer 40 preferably contains metal at a ratio of 20 volume percent or more and 80 volume percent or less. When the composite material contains metal at the ratio of 20 volume percent or more, joint strength of the heat dissipating member 22 with respect to the metal sintered material is increased. The adhesive layer 40 may be made of only a ceramic material and a metal material. Thus, the adhesive layer 40 may not contain an organic material. It is preferable that the adhesive layer 40 does not contain Ag.

A thickness (a dimension in a vertical direction in FIG. 2) of the adhesive layer 40 may be equal to or larger than 5 μm and equal to or smaller than 50 μm. When the thickness is equal to or larger than 5 μm, a thickness of the layer can be substantially even while generally used powder having a radius equal to or larger than 0.5 μm and equal to or smaller than 2 μm is used as ceramic powder and metal powder for forming the adhesive layer 40. When the thickness is equal to or smaller than 50 μm, a screen printing method is easily applied as a method of forming the adhesive layer 40.

The lead frame 30 is disposed on the front surface SF1 of the frame 21 via the brazing material layer 32 and the metallization layer 31. The metallization layer 31 is provided on the front surface SF1 of the frame 21. Specifically, the lead frame 30 is joined to the metallization layer 31 using the brazing material layer 32. The metallization layer 31 may include the sintered material containing Cu at a higher volume ratio than the metal sintered material of the heat dissipating member 22.

The lid 80 (FIG. 1) may be formed of a ceramic material, and the ceramic material may contain alumina as a main component and is substantially alumina, for example. Alternatively, the lid 80 may contain resin. The resin is a liquid crystal polymer, for example. Inorganic fillers may be dispersed in the resin, and the inorganic fillers are silica particles, for example. Dispersion of the inorganic fillers in the resin can increase strength and durability of the lid 80.

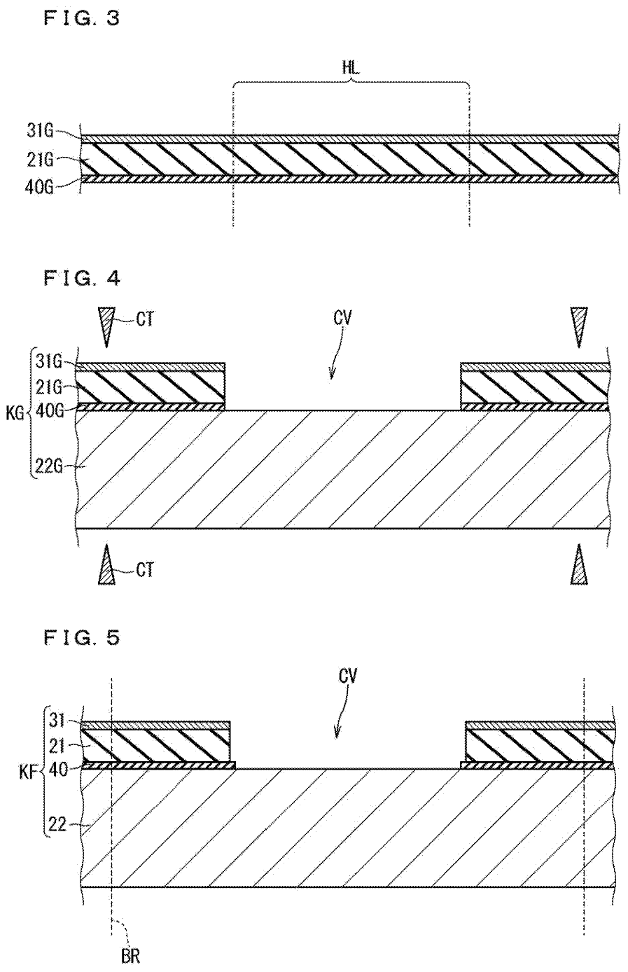

FIG. 3 to FIG. 6 are schematic cross-sectional views each illustrating first to fourth steps of the method of manufacturing the package in FIG. 2.

With reference to FIG. 3, a green sheet 21G including a portion to be the frame 21 (FIG. 2) by firing is formed. A green sheet is generally formed from slurry using a doctor blade method. The slurry is obtained by mixing powder to be a component of a sintered body with the resin, a plasticizing agent, a solvent, and the like using a ball mill. The above-mentioned powder for slurry for forming the frame 21 may be mixed powder of Al₂O₃ powder of 50 wt % or more as a main component, Si element containing powder of 5 wt % to 17 wt % in terms of SiO₂ equivalent, and Mn element containing powder of 3 wt % to 14 wt % in terms of MnO equivalent, for example. The green sheet 21G is formed by the doctor blade method using this slurry. Next, a green metallization layer 31G to be the metallization layer 31 by firing is formed on one surface (an upper surface in FIG. 3) of the green sheet 21G, and a green adhesive layer 40G to be the adhesive layer 40 by firing is formed on the other surface (a lower surface in FIG. 3) of the green sheet 21G. These may be formed by printing a paste using a screen printing method. The paste is manufactured by mixing metal powder, resin and a solvent. The printed paste is dried under conditions at a temperature of 110 °C and for five minutes, for example. Formation of the green metallization layer 31G is omitted when the metallization layer 31 (FIG. 2) is unnecessary.

The paste for the green metallization layer 31G contains metal powder. The metal powder may contain Cu powder and powder of at least one refractory metal selected from the group consisting of W and Mo. Ceramic powder may also be added as necessary. As a modification example, a green sheet formed of slurry made of a material similar to the paste may be laminated in place of the above-mentioned printing of the paste.

The paste for the green adhesive layer 40G contains metal powder and ceramic powder. The metal powder may contain Cu powder and powder of at least one refractory metal selected from the group consisting of W and Mo. As a modification example, a green sheet formed of slurry made of a material similar to the paste may be laminated in place of the above-mentioned printing of the paste.

Next, a through hole HL for constituting the cavity CV (FIG. 2) is formed. This is formed by punching, for example.

With reference to FIG. 4, a green sheet 22G to be the heat dissipating member 22 (FIG. 2) by firing is formed. The powder for slurry for forming the heat dissipating member 22 may be mixed powder including Cu powder and refractory metal powder. In this manufacturing method, differing from an impregnating method of supplying Cu by impregnation to the refractory metal which has been sintered, Cu and the refractory metal are mixed with each other in a powder state. The above-mentioned mixed powder may include ceramic powder as an additive.

Next, the green sheet 22G and the configuration illustrated in FIG. 3 are laminated each other to form a green structure KG. The green structure KG is a structure made up of a combination of the green sheet 22G (the first green member), the green sheet 21G (the second green member), and the green adhesive layer 40G (the third green member), and the green metallization layer 31G is also combined in this example. When breaking is performed as described hereinafter, a trench (not shown) may be formed in each of an upper surface and a lower surface of the green structure KG by machining using cutting edges CT or laser processing using a laser processing device (not illustrated) at a position where breaking described hereinafter is performed.

Next, the green structure KG is fired. A firing temperature is 1100 °C or more and 1400 °C or less, for example. A firing temperature of 1100 °C or more enables heating of the laminated body to a temperature at or above a melting point of Cu. The heat dissipating member 22 containing Cu can thus be formed with high quality. On the other hand, a firing temperature of 1400 °C or less can avoid a difficulty in a step caused by an excessively high firing temperature. For example, excess evaporation of Cu in firing can be avoided. As described above, plating may be performed at an optional timing after firing step. The semiconductor element 8 (FIG. 1) may be mounted at an optional timing after firing step (after plating in a case where plating is performed).

If the green adhesive layer 40G is formed on a flat metal plate as a heat dissipating member in the manner similar to the technique of Japanese Patent Application Laid-Open No. 51-132461 described above, joint strength between the heat dissipating member and the adhesive layer after firing the green adhesive layer 40G is extremely low. If the green adhesive layer 40G is formed on the metal plate made of the metal sintered material and thus microscopically having unevenness in place of the flat metal plate as described above, points with which metal powder in the green adhesive layer 40G has contact increases on a surface of the metal plate. Thus, joint strength between the adhesive layer 40 obtained by firing the green adhesive layer 40G and the metal plate slightly increases compared with the case described above. However, there is still large room for improvement. In contrast to these methods, according to the present embodiment, the green adhesive layer 40G is formed on the green sheet 22G as the heat dissipating member 22, and these are co-fired. Accordingly, metal powder in the green adhesive layer 40G penetrates the green sheet 22G more easily. Thus, joint strength between the adhesive layer 40 and the heat dissipating member 22 after firing is significantly improved compared with the two methods described above.

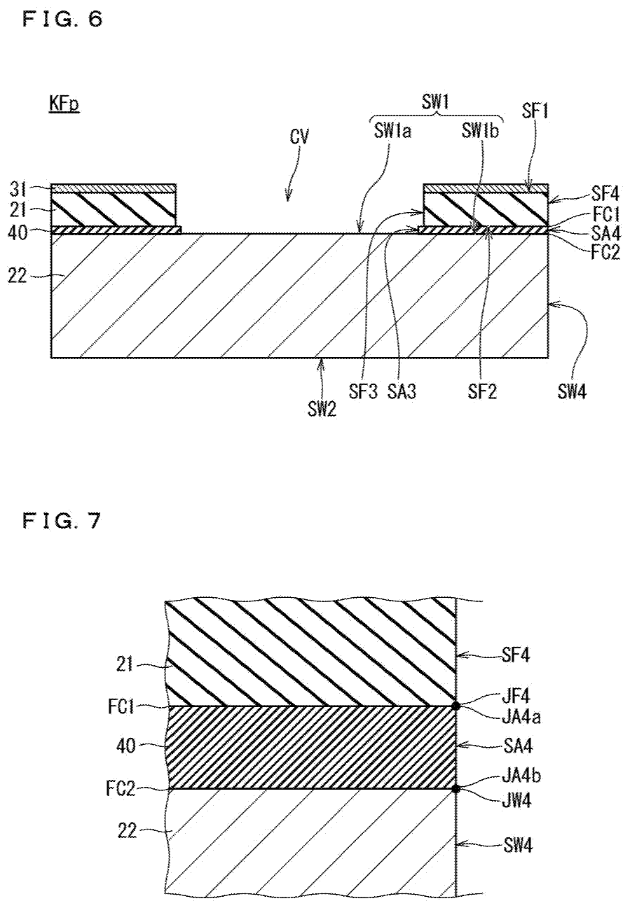

With reference to FIG. 5, a sintered body KF is obtained from the green structure KG by the above-mentioned firing. In other words, the heat dissipating member 22, the frame 21, the adhesive layer 40, and the metallization layer 31 are formed by co-firing. Next, a breaking step of generating a crack from the above-mentioned trench as a start point along a broken line BR is performed on the sintered body KF. Furthermore, with reference to also FIG. 6, a sintered body KFp is obtained from the sintered body KF (FIG. 5) by this breaking step. As a modification example, cutting processing may be performed in place of forming the trench before firing instead of the breaking step. The plurality of sintered bodies KFp may be obtained from one sintered body KF to increase manufacturing efficiency.

Furthermore, with reference to also FIG. 2, a brazing step is performed to join the lead frame 30 to the sintered body KFp via the brazing material layer 32. The package 51 is obtained as described above.

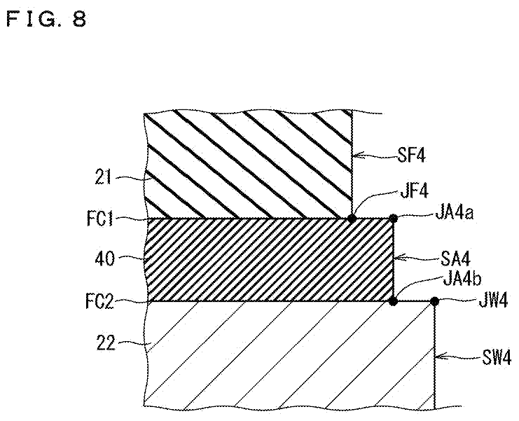

Each of FIG. 7 and FIG. 8 is a schematic partial cross-sectional view in a cross section parallel to the thickness direction illustrating one example and another example of a configuration near the outer end surface SA4 of the adhesive layer 40 in the package 51. In the cross-sectional view, the outer surface SF4 of the frame 21 includes a lower end JF4, and the outer wall surface SW4 of the heat dissipating member 22 includes an upper end JW4. As described above, as a result of breaking processing (or cutting processing) along the broken line BR (FIG. 5), the lower end JF4 and the upper end JW4 are located in substantially the same position in a direction perpendicular to the thickness direction (a lateral direction in FIG. 7 and FIG. 8), that is to say, the in-plane direction at least before the firing step. However, a slight positional deviation may occur between the lower end JF4 and the upper end JW4 in the in-plane direction as illustrated in FIG. 8, for example, by a factor such as sintering shrinkage in the firing step. Even in such a case, the positional deviation can easily be within 0.1 mm when the breaking step or the cutting step is applied. All of the four positions in total of an upper end JA4a and a lower end JA4b of the adhesive layer 40 can also easily be within a range of 0.1 mm in the in-plane direction in addition to the lower end JF4 and the upper end JW4.

According to the present embodiment 1, the adhesive layer 40 (FIG. 2) is made of the composite material containing both ceramic and metal, and the composite material is sintered with the ceramic material of the frame 21 and sintered with the metal sintered material of the heat dissipating member 22. Accordingly, practically sufficient joint strength can be ensured between the frame 21 made of the ceramic material and the heat dissipating member 22 made of the metal without brazing between the frame 21 and the heat dissipating member 22.

When the heat dissipating member 22 contains both Cu and the refractory metal, improvement of thermal conductivity of the heat dissipating member 22 by containing Cu and suppression of the coefficient of linear expansion of the heat dissipating member 22 by containing the refractory metal can be appropriately adjusted in accordance with usage purpose of the package. When the composite material of the adhesive layer 40 also contains such a material similar to the metal sintered material, joint strength between the heat dissipating member 22 and the adhesive layer 40 can be ensured more reliably by similarity of the materials.

The metallization layer 31 on the front surface of the frame 21 is made of the sintered material including Cu at a higher volume ratio than the metal sintered material of the heat dissipating member 22. Accordingly, the metallization layer 31 has a higher coefficient of linear expansion than the heat dissipating member 22. In view of a configuration that the metallization layer 31 normally has a smaller thickness than the heat dissipating member 22, when the relationship of the coefficient of linear expansion described above is established in the configuration that the frame 21 made of the ceramic material is disposed between the metallization layer 31 and the heat dissipating member 22, balance of thermal stress in the package 51 is easily achieved. Thus, warpage of the package 51 under temperature change can be suppressed. The thickness of the metallization layer 31 is preferably equal to or larger than 5 μm and equal to or smaller than 200 μm. When the thickness is equal to or larger than 5 μm, the above-mentioned balance of the thermal stress can easily be achieved; thus, the effect of suppressing warpage of the package 51 can be obtained more sufficiently. Furthermore, the metallization layer 31 can sufficiently obtain the function as the conductive layer. When the thickness is equal to or smaller than 200 μm, it is possible to make the metallization layer 31 not easily detached.

Differing from a general brazing material, the adhesive layer 40 needs not contain Ag. Accordingly, occurrence of Ag migration from the adhesive layer 40 can be avoided. Particularly, when the lead frame 30 is provided on the front surface SF1 of the frame 21, insufficient electrical insulation between the heat dissipating member 22 and the lead frame 30 caused by the migration can be avoided. If the adhesive layer 40 contains Ag as with a general brazing material layer, Ag migration easily occurs in a case where negative potential is applied to the lead frame 30 for a long period of time based on potential of the heat dissipating member 22.

With reference to FIG. 7 and FIG. 8, the positional deviation between the lower end JF4 of the outer surface SF4 of the frame 21 and the upper end JW4 of the outer wall surface SW4 of the heat dissipating member 22 in the direction perpendicular to the thickness direction is equal to or smaller than 0.1 mm. Accordingly, concentration of stress caused by the positional deviation can be suppressed. Thus, occurrence of detachment from between the lower end JF4 of the outer surface SF4 of the frame 21 and the upper end JW4 of the outer wall surface SW4 of the heat dissipating member 22 is prevented.

### Embodiment 2

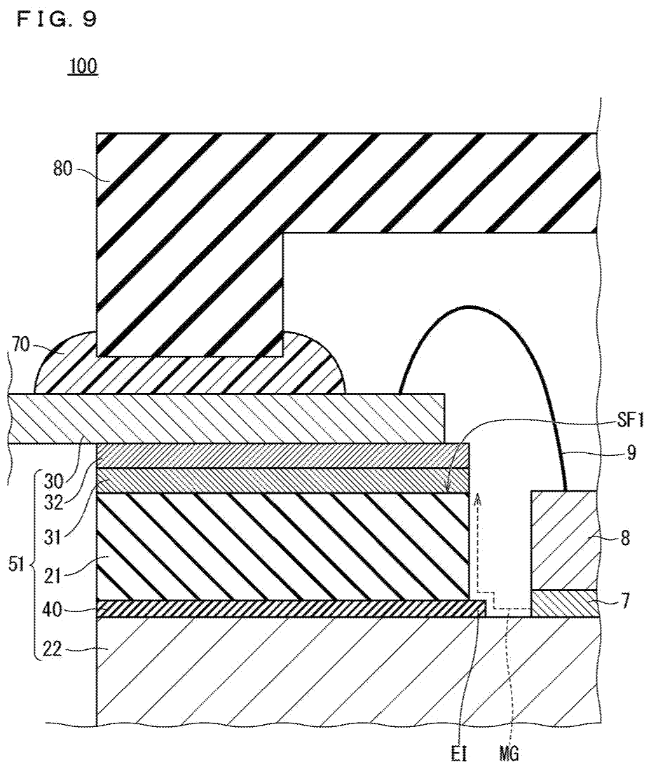

FIG. 9 is a schematic partial cross-sectional view illustrating occurrence of Ag migration in the electrical apparatus 100 including the package 51 according to the above-mentioned embodiment 1. The adhesive layer 40 includes an inner end portion EI extending into the cavity CV. Although the adhesive layer 40 needs not contain Ag as described above, the mounting material 7 needs to contain Ag in many cases. Thus, Ag migration may occur along a route MG (a broken line arrow in FIG. 9) in some cases.

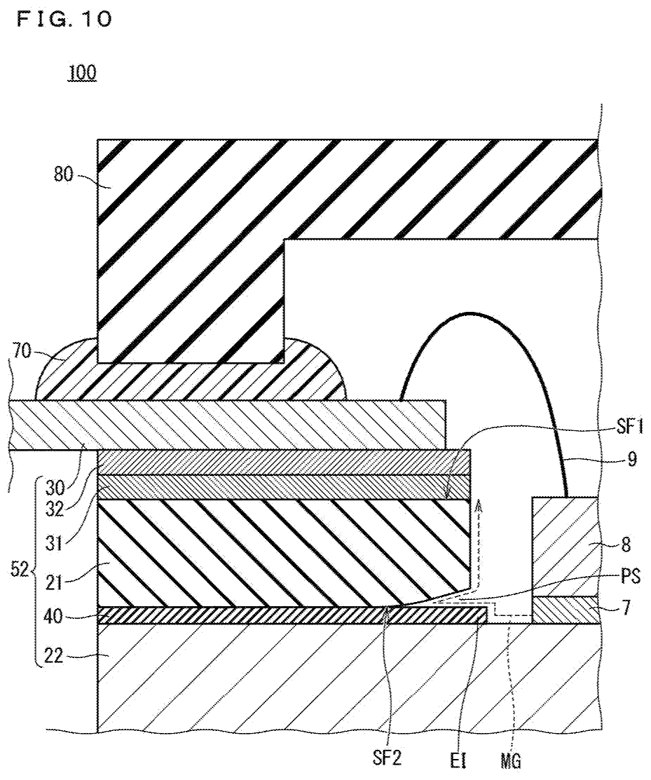

FIG. 10 is a schematic cross-sectional view illustrating a configuration of the electrical apparatus 100 according to the present embodiment 2, and the electrical apparatus 100 includes a package 52 in place of the package 51 (FIG. 9). The composite material of the adhesive layer 40 needs not contain Ag in any of the cases of the package 51 and the package 52. In the meanwhile, differing from the package 51, a space PS is provided between the inner end portion EI of the adhesive layer 40 and the facing surface SF2 of the frame 21 in the thickness direction (the vertical direction in FIG. 10) in the package 52. Since a configuration other than the above-mentioned configuration is substantially the same as the above-mentioned configuration according to the embodiment 1, the same or corresponding elements bear the same reference signs, and description thereof is not repeated.

According to the present embodiment 2, Ag migration from the mounting material 7 needs to proceed along the route MG (the broken line arrow in FIG. 10) going around the above-mentioned space PS. Suppressed accordingly is reduction of electrical insulation between the heat dissipating member 22 and the front surface SF1 of the frame 21 caused by Ag migration. Particularly, when the lead frame 30 is provided on the front surface SF1, insufficient electrical insulation between the heat dissipating member 22 and the lead frame 30 caused by the migration can be avoided.

### Embodiment 3

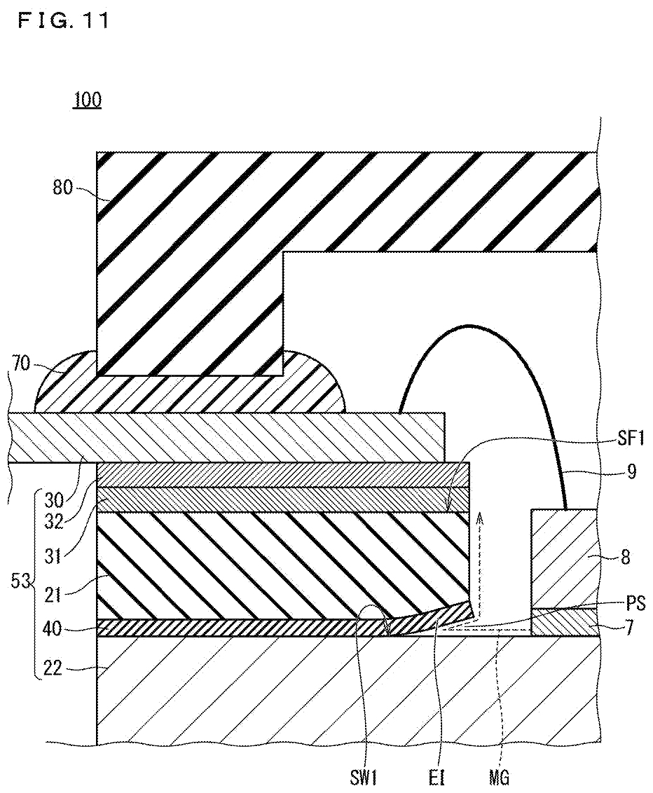

FIG. 11 is a schematic cross-sectional view illustrating a configuration of the electrical apparatus 100 according to the present embodiment 3, and the electrical apparatus 100 includes a package 53 in place of the package 51 (FIG. 9). The composite material of the adhesive layer 40 needs not contain Ag in any of the cases of the package 51 and the package 53 (FIG. 9 and FIG. 11). In the meanwhile, differing from the package 51, the space PS is provided between the inner end portion EI of the adhesive layer 40 and the upper surface SW1 of the heat dissipating member 22 in the thickness direction (the vertical direction in FIG. 11) in the package 53. Since a configuration other than the above-mentioned configuration is substantially the same as the above-mentioned configuration according to the embodiment 1, the same or corresponding elements bear the same reference signs, and description thereof is not repeated.

According to the present embodiment 3, Ag migration from the mounting material 7 needs to proceed along the route MG (the broken line arrow in FIG. 11) going around the above-mentioned space PS. Suppressed accordingly is reduction of electrical insulation between the heat dissipating member 22 and the front surface SF1 of the frame 21 caused by Ag migration. Particularly, when the lead frame 30 is provided on the front surface SF1, insufficient electrical insulation between the heat dissipating member 22 and the lead frame 30 caused by the migration can be avoided.

### Embodiment 4

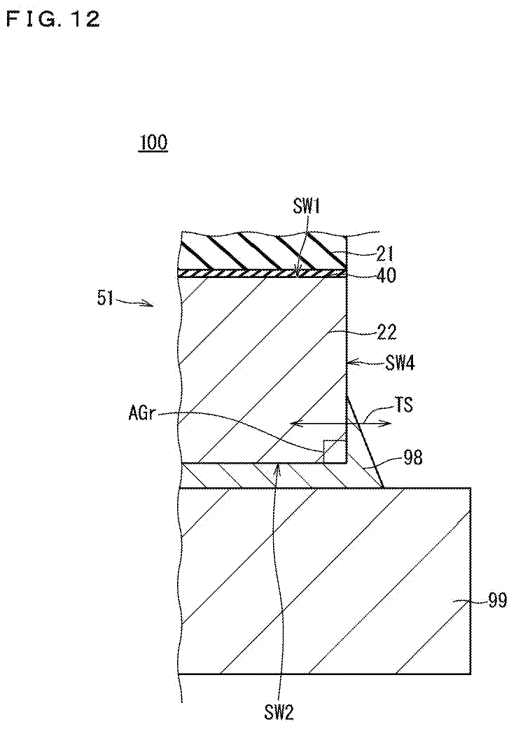

FIG. 12 is a schematic partial cross-sectional view illustrating stress TS caused by temperature change on the solder layer 98 in the electrical apparatus 100 including the package 51 according to the above-mentioned embodiment 1. The stress TS tends to occur along substantially the in-plane direction (the lateral direction in FIG. 12). In the package 51, the lower surface SW2 of the heat dissipating member 22 and the outer wall surface SW4 may make substantially a right angle AGr. In such a case, the stress TS occurs at an interface between the outer wall surface SW4 and the solder layer 98. As a result, the stress TS tends to lead to detachment at the interface.

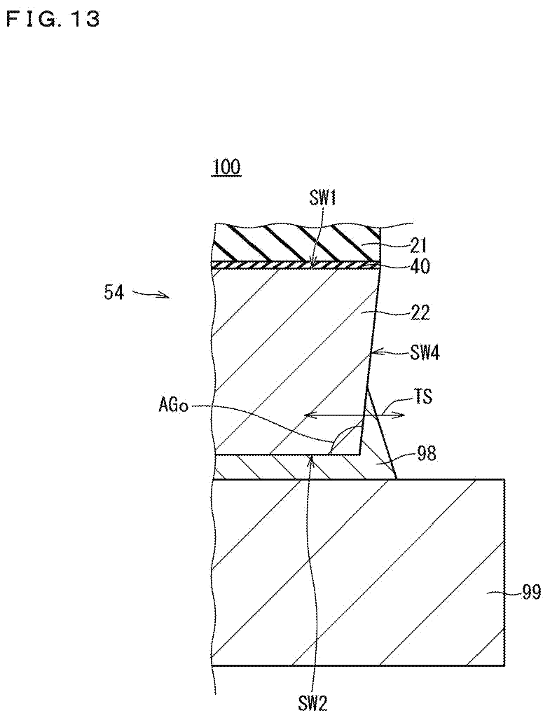

FIG. 13 is a schematic cross-sectional view illustrating a configuration of the electrical apparatus 100 according to the present embodiment 4, and the electrical apparatus 100 includes a package 54 in place of the package 51 (FIG. 12). In the package 54, the lower surface SW2 of the heat dissipating member 22 and the outer wall surface SW4 make an obtuse angle AGo. The obtuse angle AGo is equal to or larger than 92 degrees and equal to or smaller than 100 degrees, for example. The obtuse angle AGo can be obtained by buffing the package 51 (FIG. 12) having the right angle AGr while holding the package 51 with a hand, for example. Since a configuration other than the above-mentioned configuration is substantially the same as the above-mentioned configuration according to any one of the embodiments 1 to 3, the same or corresponding elements bear the same reference signs, and description thereof is not repeated.

According to the present embodiment 4, the outer wall surface SW4 is not perpendicular to the in-plane direction but is inclined with respect thereto. Accordingly, the stress TS hardly leads to detachment at the interface between the outer wall surface SW4 and the solder layer 98. Thus, it is possible to make the solder layer 98 not easily detached.

### Embodiment 5

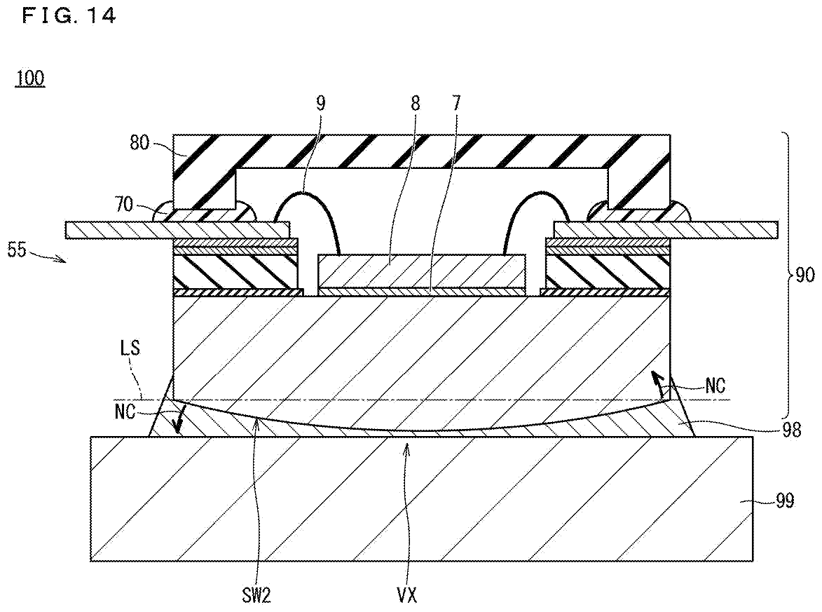

FIG. 14 is a schematic cross-sectional view illustrating a configuration of the electrical apparatus 100 according to the present embodiment 5, and the electrical apparatus 100 includes a package 55 in place of the package 51 (FIG. 2). The cross-sectional view is a cross-sectional view of a cross section parallel to the thickness direction and passing a center of the heat dissipating member 22. The lower surface SW2 of the heat dissipating member 22 may be flat in the package 51 (FIG. 1 and FIG. 2: the embodiment 1). In contrast, in the package 55 (FIG. 14), the lower surface SW2 of the heat dissipating member 22 has a convex shape VX in a center portion of the heat dissipating member 22. Since a configuration other than the above-mentioned configuration is substantially the same as the above-mentioned configuration according to any one of the embodiments 1 to 4, the same or corresponding elements bear the same reference signs, and description thereof is not repeated.

According to the present embodiment 5, when the heat dissipating member 22 is joined to the heat sink 99 (more generally, the other member) by forming the solder layer 98 using solder (more generally, a fluent material for forming the joint layer) melted by heating, the joint material is pressed to extend to a surrounding portion outside the center portion of the heat dissipating member 22 by the convex shape VX. Accordingly, joint strength of the solder layer 98 can be easily ensured at the surrounding portion around the center portion. Since the solder layer 98 is detached from the surrounding portion more easily than the center portion, the detachment of the solder layer 98 can be prevented by ensuring the joint strength of the solder layer 98 in the surrounding portion.

A reference line LS (FIG. 14) is a straight line connecting one end and the other end of the heat dissipating member 22 (a right end and a left end in FIG. 14). The convex shape VX protrudes more than the reference line LS. A height difference of the lower surface SW2 in a direction perpendicular to the reference line LS based on the reference line LS is preferably equal to or larger than 10 μm and equal to or smaller than 100 μm. When the height difference is equal to or larger than 10 μm, the above-mentioned effect can be obtained more efficiently. When the height difference is equal to or smaller than 100 μm, formation of a position where the thickness of the solder layer 98 is locally too large can be prevented. Since thermal conductivity of the solder layer 98 is not necessarily high compared with that of the heat dissipating member 22, heat dissipation characteristics may be deteriorated when the thickness of the solder layer 98 is too large.

Differing from the embodiment 6 described hereinafter, in the present embodiment 5, the lower surface SW2 does not include a portion located to be depressed from the reference line LS (a portion on an upper side than the reference line LS in FIG. 14). Thus, the height difference in the present embodiment 5 is equal to a dimension of the convex shape VS protruding from the reference line LS in the direction perpendicular to the reference line LS.

### Embodiment 6

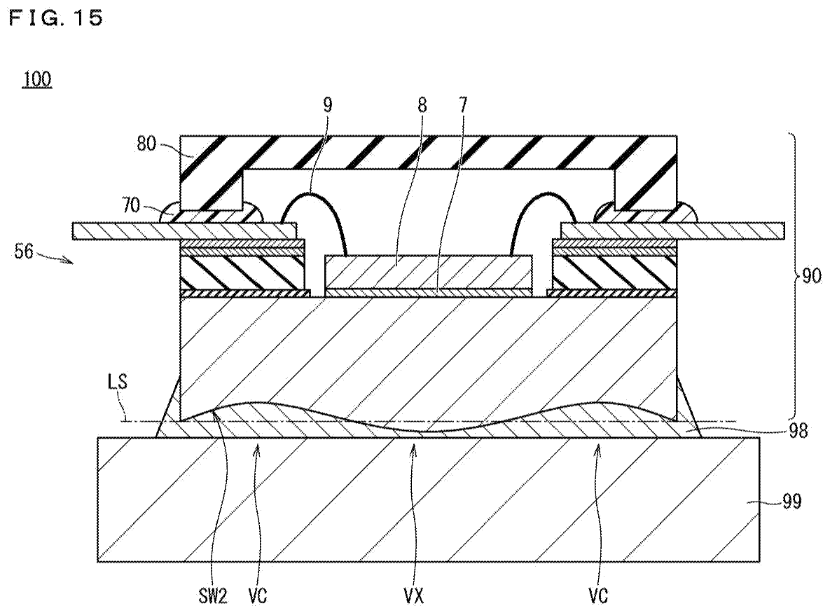

FIG. 15 is a schematic cross-sectional view illustrating a configuration of the electrical apparatus 100 according to the present embodiment 6, and the electrical apparatus 100 includes a package 56 in place of the package 55 (FIG. 14). The cross-sectional view is also a cross-sectional view of a cross section parallel to the thickness direction and passing the center of the heat dissipating member 22 in the manner similar to the above-mentioned FIG. 14. In the package 56 (FIG. 15), the lower surface SW2 of the heat dissipating member 22 includes a concave shape VC outside the center portion in addition to the convex shape VX in the above-mentioned embodiment 5. It is sufficient that thermal processing is performed while a weight is disposed in a position where the concave shape VC is to be formed in the cavity CV of the package (FIG. 14: the embodiment 5), for example. Since a configuration other than the above-mentioned configuration is substantially the same as the above-mentioned configuration according to the embodiment 5, the same or corresponding elements bear the same reference signs, and description thereof is not repeated.

According to the present embodiment 6, the convex shape VX is included; thus, an effect similar to that of the embodiment 5 can be obtained. Herein, the lower surface SW2 of the heat dissipating member 22 has a simple convex shape in the package 55 (FIG. 14: the embodiment 5). When the solder layer 98 is formed using solder (more generally, a fluent material for forming the joint layer) melted by heating to join the heat dissipating member 22 to the heat sink 99 (more generally, the other member), the lower surface SW2 of the package 55 is easily inclined with respect to a horizontal surface without intention based on the protruding portion of the convex shape VX as the pivot point as illustrated by an arrow NC (FIG. 14). In contrast, according to the present embodiment 6, the lower surface SW2 of the heat dissipating member 22 also includes the concave shape VC. Thus, the end of the lower surface SW2 of the heat dissipating member 22 can get close to the heat sink 99. Accordingly, inclination of the heat dissipating member 22 can be suppressed.

The concave shape VC is located to be depressed from the reference line LS (above the reference line LS in FIG. 15). Thus, a height difference in the present embodiment 6 is a sum of a dimension of the convex shape VX protruding from the reference line LS in the direction perpendicular to the reference line LS and a dimension of the convex shape VC depressed from the reference line LS in the direction perpendicular to the reference line LS. Also in the present embodiment 6, the height difference in the direction perpendicular to the reference line LS is preferably equal to or larger than 10 μm and equal to or smaller than 100 μm in the manner similar to the above-mentioned embodiment 5.

### Embodiment 7

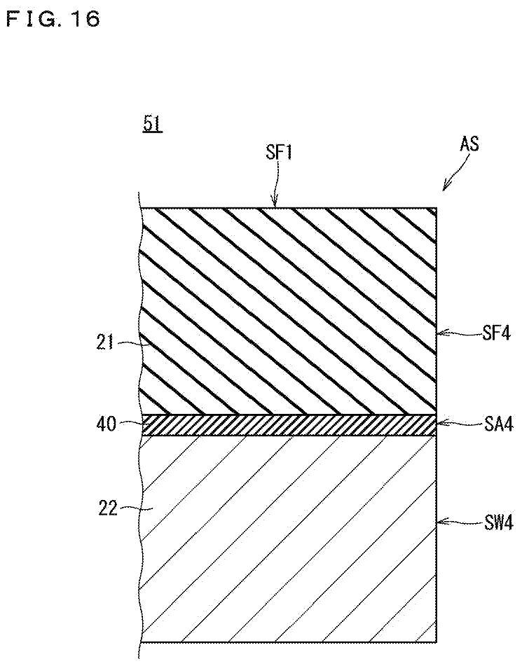

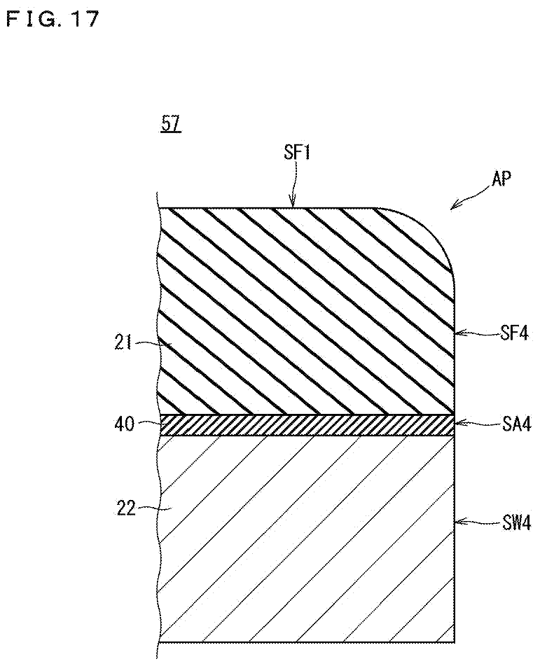

FIG. 16 is a schematic partial cross-sectional view illustrating an example of a configuration near a corner portion AS made by the front surface SF1 and the outer surface SF4 of the frame 21 in the package 51 according to the above-mentioned embodiment 1. The corner portion AS may be a corner portion which is not rounded. FIG. 17 is a schematic partial cross-sectional view illustrating an example of a configuration near a corner portion AP made by the front surface SF1 and the outer surface SF4 of the frame 21 in the package 57 according to the present embodiment 7. The corner portion AP is rounded and specifically has a curvature radius equal to or larger than 0.1 mm and equal to or smaller than 0.5 mm. Since a configuration other than the above-mentioned configuration is substantially the same as the above-mentioned configuration according to any one of the embodiments 1 to 6, the same or corresponding elements bear the same reference signs, and description thereof is not repeated.

According to the present embodiment, the corner portion AP of the frame 21 has the curvature radius equal to or larger than 0.1 mm and equal to or smaller than 0.5 mm. Since the curvature radius is equal to or larger than 0.1 mm, the corner portion AP can be hard to be cracked upon receiving impact. Since the curvature radius is equal to or smaller than 0.5 mm, excess reduction of the area of the front surface SF1 of the frame 21 caused by rounding the corner portion AP is avoided. Particularly, when the lead frame 30 is provided on the front surface SF1 of the frame 21, the area of the front surface SF1 of the frame 21 is sufficiently ensured; thus, the joint area between the front surface SF1 of the frame 21 and the lead frame 30 is easily ensured. Thus, these can be joined to each other with large strength.

### Embodiment 8

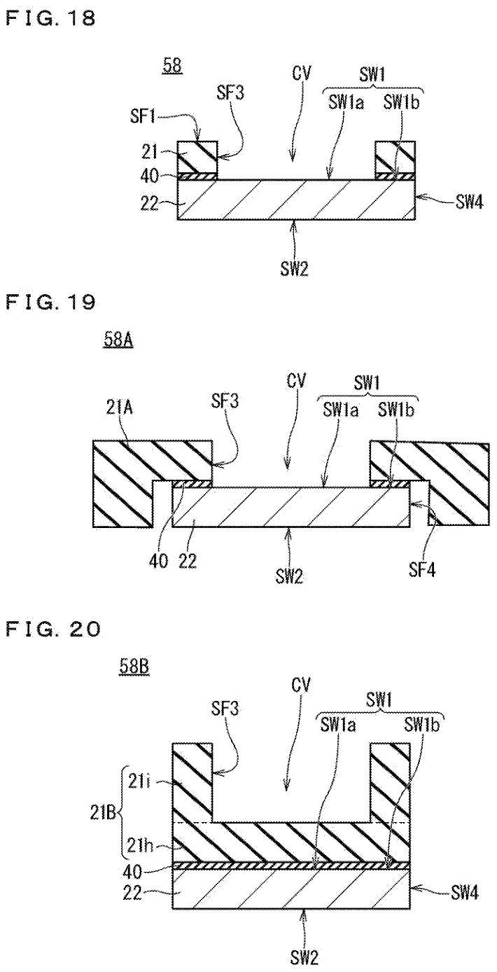

FIG. 18 is a schematic cross-sectional view illustrating a configuration of a package 58 according to an embodiment 8. The package 58 has a configuration substantially similar to the frame 21, the heat dissipating member 22, and the adhesive layer 40 included in the package 51 (FIG. 3) according to the above-mentioned embodiment 1. The lead frame 30 may be applied to the package 58 and a modification example described hereinafter in the manner similar to the package 51 (FIG. 2), and furthermore, the metallization layer 31 for the lead frame 30 may be applied. A metallization layer not for the lead frame 30 but for the other usage purpose may be formed in place of or in addition to the metallization layer 31 for the lead frame 30 on the front surface SF1 of the frame 21 of the package 58. A material of the metallization layer may be similar to that described above as the material of the metallization layer 31.

FIG. 19 is a schematic cross-sectional view illustrating a configuration of a package 58A according to a modification example 1 of the embodiment 8. The package 58A includes a frame 21A in place of the frame 21 (FIG. 18). The frame 21A (specifically, an inner portion thereof) is disposed on a surrounding edge surface SW1b of the upper surface SW1 of the heat dissipating member 22 via the adhesive layer 40. With respect to the position in the thickness direction, the frame 21A extends into a range between the upper surface SW1 and the lower surface SW2 of the heat dissipating member 22 from the position above the upper surface SW1 of the heat dissipating member 22. The frame 21A may further extend, and extends to the position of the lower surface SW2 of the heat dissipating member 22 in the example illustrated in FIG. 19. The frame 21A is located away from the heat dissipating member 22.

FIG. 20 is a schematic cross-sectional view illustrating a configuration of a package 58B according to a modification example 2 of the embodiment 8. The package 58B includes a frame 21B in place of the frame 21 (FIG. 17). The frame 21B includes a plate-like base portion 21h disposed on the upper surface SW1 of the heat dissipating member 22 via the adhesive layer 40 and a frame 21i located on the base portion 21h. A boundary between the base portion 21h and the frame 21i (a broken line in FIG. 20) may be virtual. The frame 21i includes the inner surface SF3 of the frame 21B in the present modification example 2. Differing from the embodiment 8 (FIG. 18), the cavity surface SW1a of the upper surface SW1 of the heat dissipating member 22 faces the cavity CV via the adhesive layer 40 and the base portion 21h of the frame 21B in the present modification example 2.

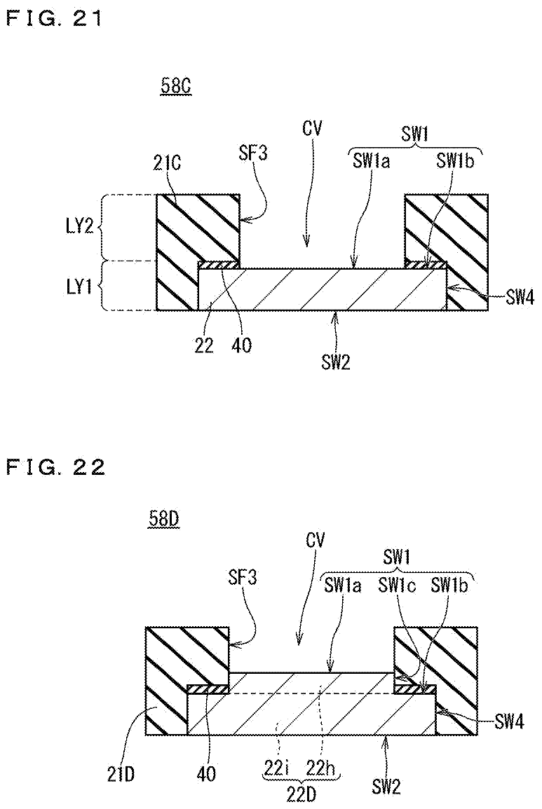

FIG. 21 is a schematic cross-sectional view illustrating a configuration of a package 58C according to a modification example 3 of the embodiment 8. The package 58C includes a frame 21C in place of the frame 21 (FIG. 18). The frame 21C (specifically, an inner portion thereof) is disposed on the surrounding edge surface SW1b of the upper surface SW1 of the heat dissipating member 22. With respect to the position in the thickness direction, the frame 21C extends into a range between the upper surface SW1 and the lower surface SW2 of the heat dissipating member 22 from the position above the upper surface SW1 of the heat dissipating member 22. The frame 21C may further extend, and extends to the position of the lower surface SW2 of the heat dissipating member 22 in the example illustrated in FIG. 21. The outer wall surface SW4 of the heat dissipating member 22 has contact with the frame 21C.

The package 58C can be manufactured by firing a laminated body of a lower layer LY1 and an upper layer LY2. The lower layer LY1 is formed as follows, for example. Firstly, a first unfired layer made of a material to be the frame 21C by firing is formed. Next, a through hole corresponding to a region in which the heat dissipating member 22 is disposed is formed in the first unfired layer using a mold. Next, a second unfired layer including a portion to be the heat dissipating member 22 and the adhesive layer 40 by firing is formed on the first unfired layer to cover the above-mentioned through hole. Next, the above-mentioned portion of the second unfired layer is pressed into the above-mentioned through hole using the above-mentioned mold again. Next, a portion which is not pressed by the mold, in other words, a portion remaining on the upper surface of the first unfired layer in the second unfired layer is removed. The lower layer LY1 is thereby obtained. The upper layer LY2 is obtained by removing a portion corresponding to the cavity CV from the unfired layer made of the material to be frame 21C by firing. The laminated body of the lower layer LY1 and the upper layer LY2 is fired to obtain the package 58C.

As a further modification of the present modification example 3, an adhesive layer (not shown) made of a ceramic material may be provided between a portion included in the lower layer LY1 and a portion included in the upper layer LY2 in the frame 21C. The adhesive layer can be formed by applying a ceramic paste on the first unfired layer before the second unfired layer is formed on the first unfired layer. This application is performed before the through hole is formed, for example.

FIG. 22 is a schematic cross-sectional view illustrating a configuration of a package 58D according to a modification example 4 of the embodiment 8. The package 58D includes the heat dissipating member 22D and the frame 21D in place of the heat dissipating member 22 and the frame 21 (FIG. 18). The frame 21D (specifically, an inner portion thereof) is disposed on the surrounding edge surface SW1b of the upper surface SW1 of the heat dissipating member 22D. The heat dissipating member 22D includes a support portion 22i and a cavity portion 22h provided on a part of the support portion 22i. A boundary between the cavity portion 22h and the support portion 22i (a broken line in FIG. 22) may be virtual. The upper surface SW1 of the heat dissipating member 22D includes the cavity surface SW1a made up of the cavity portion 22h and the surrounding edge surface SW1b made up of the support portion 22i. In the upper surface SW1 of the heat dissipating member 22D, the position of the cavity surface SW1a and the position of the surrounding edge surface SW1b are different from each other in the thickness direction, and the latter position is closer to the lower surface SW2. The cavity surface SW1a and the surrounding edge surface SW1b may be surfaces substantially parallel to each other. The upper surface SW1 may further include a sidewall surface SW1c made up of the cavity portion 22h and mutually connecting the cavity surface SW1a and the surrounding edge surface SW1b. The sidewall surface SW1c may extend along substantially the thickness direction. The sidewall surface SW1c may include a portion having contact with the frame 21D. A lower portion (an end portion connected to the surrounding edge surface SW1b) of the sidewall surface SW1c may have contact with the end surface of the adhesive layer 40. The outer wall surface SW4 of the support portion 22i may have contact with the frame 21D. The package 58D can be manufactured by a manufacturing method similar to the above-mentioned method of manufacturing the package 58C (FIG. 21).

### Embodiment 9

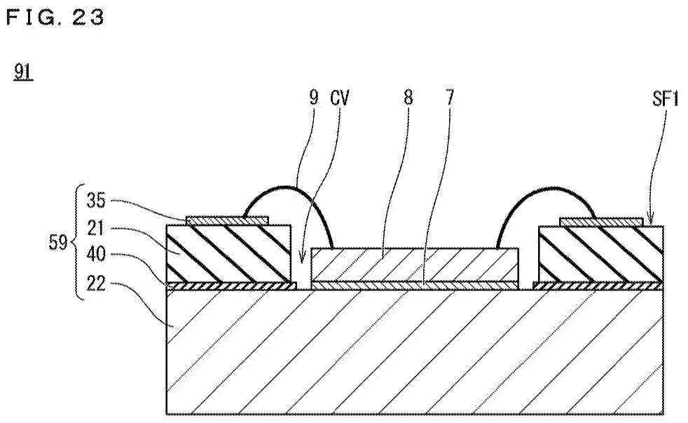

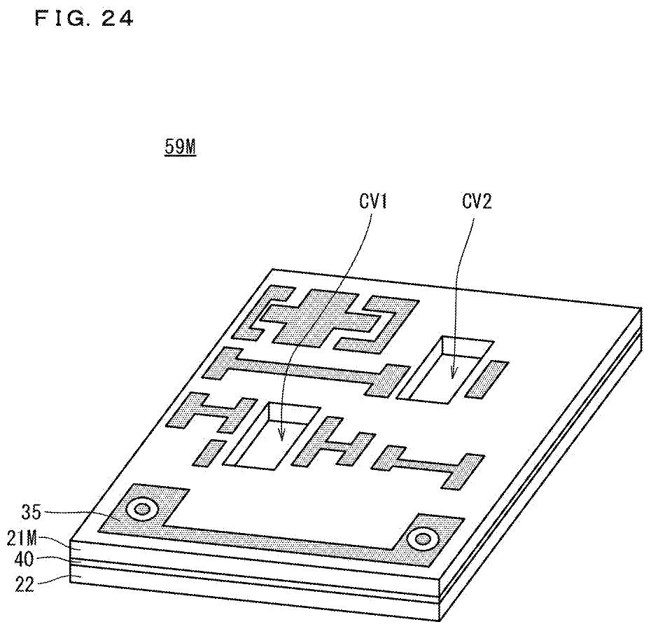

FIG. 23 is a schematic cross-sectional view illustrating a configuration of a semiconductor module 91 (an electrical apparatus) according to an embodiment 9. The semiconductor module 91 includes the package 59 with the cavity CV, a semiconductor element 8 housed in the cavity CV, and the mounting material 7 for mounting the semiconductor element 8 on the package 59. The semiconductor module 91 may include wires 9 as wiring members for the semiconductor element 8. The semiconductor module 91 does not include the lid 80 (FIG. 1: the embodiment 1), thus also does not include the adhesive portion 70 for bonding the lid 80. The semiconductor module 91 may be used in place of the semiconductor module 90 in the electrical apparatus 100 (FIG. 1: the embodiment 1).

The package 59 includes the heat dissipating member 22, the frame 21, and the adhesive layer 40 in the manner similar to the package 51 (FIG. 2: the embodiment 1). The package 59 further includes an electrode layer 35 on the front surface SF1. Plating may also be performed on the package 59 in the manner similar to the package 51 (FIG. 2: the embodiment 1). In other words, a plating film (not shown) may also be provided to the package 59.

Differing from the package 51 (FIG. 2: the embodiment 1), the package 59 does not include the lead frame 30, thus also does not include the brazing material layer 32 and the metallization layer 31 for joining the lead frame 30. The lead frame 30 has a function as an external terminal in the package 51. However, the electrode layer 35 may have a function as an external terminal in the package 59. For this purpose, the electrode layer 35 may further extend from a position on the front surface SF1 as necessary. A function of the electrode layer 35 is limited to the function as the external terminal. The electrode layer 35 may have a function as a circuit pattern together with the above-mentioned function or in place thereof as illustrated in FIG. 24 (an embodiment 10 described hereinafter), for example. The electrode layer 35 may be omitted depending on a usage purpose of the package.

In the semiconductor module 91 including the package 59, the electrode layer 35 and the semiconductor element 8 may be electrically connected to each other by the wire 9. In the step of attaching the wire 9, a surface (an upper surface in FIG. 23) of the electrode layer 35 of the package 59 is exposed. When plating is performed on the package 59, plating may be performed on the surface of the electrode layer 35 exposed as described above. However, the wire 9 needs not necessarily be connected to the electrode layer 35. The wire 9 may be omitted depending on the design of the electrical apparatus.

A material of the electrode layer 35 may be similar to that of the metallization layer 31 (FIG. 2: the embodiment 1). A method of forming the electrode layer 35 may also be similar to that of forming the metallization layer 31.

Since a configuration other than the above-mentioned configuration is substantially the same as the above-mentioned configuration according to any one of the embodiments 1 to 7, the same or corresponding elements bear the same reference signs, and description thereof is not repeated. The electrode layer 35 in the present embodiment 9 may be applied to the embodiment 8.

### Embodiment 10

FIG. 24 is a schematic perspective view illustrating a configuration of a package 59M according to an embodiment 10. A dot pattern is assigned to the electrode layer 35 in FIG. 24 to easily see FIG. 24. The package 59M includes a frame 21M. The frame 21M includes an inner surface surrounding a plurality of cavities CV1 and CV2. The electrode layer 35 has a function as a wiring pattern in the example illustrated in FIG. 24. As a modification example, the wire 9 may be connected to the electrode layer 35 as illustrated in FIG. 23 (the embodiment 9).

A configuration other than the above-mentioned configuration is substantially the same as the above-mentioned configuration according to the embodiment 9, so that the same or corresponding elements bear the same reference signs, and description thereof is not repeated. The plurality of cavities may also be provided to the package according to any of the above-mentioned embodiments as with the present embodiment 10 in place of one cavity.

The embodiments described above may be freely combined with each other. The present invention has been described in detail, the foregoing description is in all aspects illustrative and not restrictive. It is therefore understood that numerous modifications and variations can be devised without departing from the scope of the invention.

### Appendix

The specification includes a disclosure for Aspects described hereinafter.

Aspect 1 is a package having a cavity in which an electrical component is to be housed. The package includes a heat dissipating member made of a metal sintered material, a frame made of a ceramic material, and an adhesive layer. The heat dissipating member includes an upper surface facing the cavity and a lower surface opposite to the upper surface. The frame includes a facing surface facing the upper surface of the heat dissipating member in a thickness direction, a front surface opposite to the facing surface, an inner surface surrounding the cavity, and an outer surface opposite to the inner surface. The adhesive layer includes a first interface having contact with the facing surface of the frame, a second interface opposite to the first interface and having contact with the upper surface of the heat dissipating member, and an outer wall surface mutually connecting the upper surface and the lower surface. The adhesive layer is made of a composite material including both ceramic and metal, and the composite material is sintered with the ceramic material of the frame at the first interface and sintered with the metal sintered material of the heat dissipating member at the second interface.

Aspect 2 is the package according to Aspect 1, wherein the metal sintered material contains copper and at least one refractory metal selected from the group consisting of tungsten and molybdenum.

Aspect 3 is the package according to Aspect 2, wherein the metal of the composite material of the adhesive layer contains copper and at least one refractory metal selected from the group consisting of tungsten and molybdenum.

Aspect 4 is the package according to Aspect 2 or 3 further including a metallization layer provided on the front surface of the frame and made of a sintered material containing copper at a higher volume ratio than the metal sintered material of the heat dissipating member.

Aspect 5 is the package according to any one of Aspects 1 to 4, wherein the composite material of the adhesive layer does not contain silver, the adhesive layer includes an inner end portion extending inside the cavity, and a space is provided between the inner end portion of the adhesive layer and the facing surface of the frame or the upper surface of the heat dissipating member in the thickness direction.

Aspect 6 is the package according to any one of Aspects 1 to 5, wherein the lower surface of the heat dissipating member and the outer wall surface make an obtuse angle.

Aspect 7 is the package according to any one of Aspects 1 to 6, wherein the lower surface of the heat dissipating member has a convex shape in a center portion of the heat dissipating member.

Aspect 8 is the package according to Aspect 7, wherein the lower surface of the heat dissipating member has a concave shape outside the center portion.

Aspect 9 is the package according to any one of Aspects 1 to 8, wherein the adhesive layer does not contain silver.

Aspect 10 is the package according to any one of Aspects 1 to 9, wherein in a cross-sectional view parallel to the thickness direction, the outer surface of the frame includes a lower end, the outer wall surface of the heat dissipating member includes an upper end, and a positional deviation between the lower end and the upper end in a direction perpendicular to the thickness direction is equal to or smaller than 0.1 mm.

Aspect 11 is the package according to any one of Aspects 1 to 10, wherein a corner portion made by the front surface and the outer surface of the frame has a curvature radius equal to or larger than 0.1 mm and equal to or smaller than 0.5 mm.

Aspect 12 is the package according to any one of Aspects 1 to 11 further including a metal terminal provided on the front surface of the frame.

Aspect 13 is an electrical apparatus including the package according to Aspect 5, the electrical component housed in the cavity of the package, and a mounting material containing silver for mounting the electrical component on the package.

Aspect 14 is a method of manufacturing a package for manufacturing the package according to any one of Aspects 1 to 12 including: forming a green structure made up of a combination of a first green member to be made into the heat dissipating member by being fired, a second green member to be made into the frame by being fired, and a third green member to be made into the adhesive layer by being fired; and firing the green structure.

According to the above-mentioned Aspect 1, the adhesive layer is made of the composite material containing both ceramic and metal, and the composite material is sintered with the ceramic material of the frame and sintered with the metal sintered material of the heat dissipating member. Accordingly, practically sufficient joint strength can be ensured between the frame made of the ceramic material and the heat dissipating member made of the metal without brazing between the frame and the heat dissipating member.

According to the above-mentioned Aspect 2, improvement of thermal conductivity of the heat dissipating member by containing copper and suppression of a coefficient of linear expansion of the heat dissipating member by containing the refractory metal can be appropriately adjusted in accordance with usage purpose of the package. Furthermore, according to the above-mentioned Aspect 3, the composite material of the adhesive layer includes a material similar to the metal sintered material of the heat dissipating member. Accordingly, joint strength can be ensured more reliably.

According to the above-mentioned Aspect 4, the metallization layer on the surface of the frame is made of the sintered material containing copper at the higher volume ratio than the metal sintered material of the heat dissipating member. Accordingly, the metallization layer has a higher coefficient of linear expansion than the heat dissipating member. In view of a configuration that the metallization layer normally has a smaller thickness than the heat dissipating member, when the relationship of the coefficient of linear expansion described above is established in the configuration that the frame made of the ceramic material is disposed between the metallization layer and the heat dissipating member, balance of thermal stress in the package is easily achieved. Thus, warpage of the package under temperature change can be suppressed.

According to the above-mentioned Aspect 5 or 13, the adhesive layer includes the inner end portion extending inside the cavity, and the space is provided between the inner end portion of the adhesive layer and the facing surface of the frame or the upper surface of the heat dissipating member in the thickness direction. Accordingly, when the electrical component is mounted by the mounting material containing silver, migration of silver from the mounting material needs to proceed while detouring around the above-mentioned space. Suppressed accordingly is reduction of electrical insulation between the heat dissipating member and the surface of the frame caused by migration of silver. Particularly, when the metal terminal is provided on the surface of the frame as with the above-mentioned Aspect 12, insufficient electrical insulation between the heat dissipating member and the metal terminal caused by the migration can be avoided.

According to the above-mentioned Aspect 6, the lower surface and the outer wall surface of the heat dissipating member make the obtuse angle. This makes it possible to make the joint layer for joining the heat dissipating member to the other member not easily detached.

According to the above-mentioned Aspect 7, the lower surface of the heat dissipating member has the convex shape in the center portion of the heat dissipating member. Accordingly, when the joint layer is formed using the joint material having flowability to join the heat dissipating member to the other member, the joint material is pressed to extend to a surrounding portion outside the center portion of the heat dissipating member by the convex shape. Accordingly, joint strength of the joint layer can be easily ensured at the surrounding portion around the center portion. Since the joint layer is detached from the surrounding portion more easily than the center portion, the detachment of the joint layer can be prevented by ensuring the joint strength of the joint layer in the surrounding portion. Furthermore, according to the above-mentioned Aspect 8, the lower surface of the heat dissipating member has the concave shape outside the center portion of the heat dissipating member. When the lower surface of the heat dissipating member has a simple convex shape, the lower surface of the heat dissipating member is easily inclined without intention with a protruding portion of the convex shape as a pivot point. However, when the lower surface of the heat dissipating member has the concave shape, this inclination can be suppressed.

According to the above-mentioned Aspect 9, the adhesive layer does not contain silver. Accordingly, occurrence of migration of silver from the adhesive layer can be avoided. Particularly, when the metal terminal is provided on the surface of the frame as with the above-mentioned Aspect 12, insufficient electrical insulation between the heat dissipating member and the metal terminal caused by the migration can be avoided.

According to the above-mentioned Aspect 10, the positional deviation between the lower end of the outer surface of the frame and the upper end of the outer wall surface of the heat dissipating member in the direction perpendicular to the thickness direction is equal to or smaller than 0.1 mm. Accordingly, concentration of stress caused by the positional deviation can be suppressed. Thus, occurrence of detachment from between the lower end of the outer surface of the frame and the upper end of the outer wall surface of the heat dissipating member is prevented.

According to the above-mentioned Aspect 11, the corner portion made by the surface and the outer surface of the frame has the curvature radius equal to or larger than 0.1 mm and equal to or smaller than 0.5 mm. Since the curvature radius is equal to or larger than 0.1 mm, the corner portion of the frame can be hard to be cracked upon receiving impact. Since the curvature radius is equal to or smaller than 0.5 mm, excess reduction of an area of the front surface of the frame caused by rounding the corner portion is avoided. Particularly, when the metal terminal is provided on the surface of the frame as with the above-mentioned Aspect 12, the area of the surface of the frame is sufficiently ensured; thus, a joint area between the surface of the frame and the metal terminal can easily be ensured. Thus, these can be joined to each other with large strength.

According to the above-mentioned Aspect 14, the heat dissipating member, the frame, and the adhesive layer can be formed by co-firing.

What is claimed is:

1. A metal-ceramic composite component, comprising:
a heat dissipating member including an upper surface and a lower surface opposite to the upper surface, and made of a metal sintered material;
a ceramic body including a facing surface facing the upper surface of the heat dissipating member in a thickness direction and a front surface opposite to the facing surface, and made of a ceramic material; and
an adhesive layer including a first interface having contact with the facing surface of the ceramic body and a second interface opposite to the first interface and having contact with the upper surface of the heat dissipating member, wherein
the adhesive layer is made of a composite material including both ceramic and metal, and the composite material is sintered with the ceramic material of the ceramic body at the first interface and sintered with the metal sintered material of the heat dissipating member at the second interface.

2. The metal-ceramic composite component according to claim 1, wherein
the metal-ceramic composite component is a package in which an electrical component is to be housed, and
the heat dissipating member includes an outer wall surface connecting the upper surface and the lower surface.

3. The metal-ceramic composite component according to claim 2, wherein
the package has a cavity in which the electrical component is to be housed,
the upper surface of the heat dissipating member faces the cavity, and
the ceramic body is a frame including an inner surface surrounding the cavity and an outer surface opposite to the inner surface.

4. The metal-ceramic composite component according to claim 1, wherein
the metal sintered material contains copper and at least one refractory metal selected from the group consisting of tungsten and molybdenum.

5. The metal-ceramic composite component according to claim 4, wherein
the metal of the composite material of the adhesive layer contains copper and at least one refractory metal selected from the group consisting of tungsten and molybdenum.

6. The metal-ceramic composite component according to claim 4, further comprising
a metallization layer provided on the front surface of the ceramic body and made of a sintered material containing copper at a higher volume ratio than the metal sintered material of the heat dissipating member.

7. The metal-ceramic composite component according to claim 3, wherein
the composite material of the adhesive layer does not contain silver, and
the adhesive layer includes an inner end portion extending inside the cavity, and a space is provided between the inner end portion of the adhesive layer and the facing surface of the ceramic body or the upper surface of the heat dissipating member in the thickness direction.

8. The metal-ceramic composite component according to claim 2, wherein
the lower surface of the heat dissipating member and the outer wall surface make an obtuse angle.

9. The metal-ceramic composite component according to claim 1, wherein
the lower surface of the heat dissipating member has a convex shape in a center portion of the heat dissipating member.

10. The metal-ceramic composite component according to claim 9, wherein
the lower surface of the heat dissipating member has a concave shape outside the center portion.

11. The metal-ceramic composite component according to claim 1, wherein
the adhesive layer does not contain silver.

12. The metal-ceramic composite component according to claim 3, wherein
in a cross-sectional view parallel to the thickness direction, the outer surface of the ceramic body includes a lower end, the outer wall surface of the heat dissipating member includes an upper end, and a positional deviation between the lower end and the upper end in a direction perpendicular to the thickness direction is equal to or smaller than 0.1 mm.

13. The metal-ceramic composite component according to claim 3, wherein
a corner portion made by the front surface and the outer surface of the ceramic body has a curvature radius equal to or larger than 0.1 mm and equal to or smaller than 0.5 mm.

14. The metal-ceramic composite component according to claim 1, further comprising
a metal terminal provided on the front surface of the ceramic body.

15. An electrical apparatus, comprising:
the metal-ceramic composite component according to claim 7;
the electrical component housed in the cavity of the metal-ceramic composite component; and
a mounting material containing silver for mounting the electrical component on the metal-ceramic composite component.

16. A method of manufacturing the metal-ceramic composite component for manufacturing the metal-ceramic composite component according to claim 1, comprising:
forming a green structure made up of a combination of a first green member to be made into the heat dissipating member by being fired, a second green member to be made into the ceramic body by being fired, and a third green member to be made into the adhesive layer by being fired; and
firing the green structure.
